(19) United States
(12) Patent Application Publication
(10) Pub. No.: US 2025/0338654 A1
(43) Pub. Date: Oct. 30, 2025

(54) IMAGE SENSOR

(71) Applicant: VisEra Technologies Company Ltd., Hsin-Chu City (TW)

(72) Inventors: Yu-Fu WU, Hsin-Chu City (TW); Chun-Yuan WANG, Hsin-Chu City (TW); Po-Hsiang WANG, Hsin-Chu City (TW)

(21) Appl. No.: 18/945,901

(22) Filed: Nov. 13, 2024

Related U.S. Application Data
(60) Provisional application No. 63/639,321, filed on Apr. 26, 2024.

(51) Int. Cl. H01L 27/146

(52) U.S. Cl. CPC H10F 39/8053; H10F 39/18; H10F 39/80

(57) ABSTRACT

The image sensor includes a photoelectric conversion layer, a color filter layer, an enhancement layer, a chromatic dispersion layer, and a router layer. The photoelectric conversion layer includes a plurality of photodiodes and a plurality of deep trench isolations separating the photodiodes. The enhancement layer is disposed on the color filter layer, wherein the enhancement layer includes a plurality of first pillars, a filling, and a first transverse layer. The router layer is disposed on the chromatic dispersion layer, wherein the router layer includes a second transverse layer and a plurality of second pillars. A critical dimension of the second pillars is smaller than a critical dimension of the first pillars.

### CROSS-REFERENCE TO RELATED APPLICATION

This application claims priority to U.S. Provisional Application Ser. No. 63/639,321, filed Apr. 26, 2024, which is herein incorporated by reference in its entirety.

### BACKGROUND

### Field of Invention

The present invention relates to an image sensor. More particularly, the present invention relates to an enhancement layer and a router layer in the image sensor.

### Description of Related Art

In the field of complementary metal oxide semiconductor (CMOS) image sensor (also known as CIS), quantum efficiency (QE) and angular response would affected the performance of the image sensor. A metasurface layer or a lens layer is usually formed in the image sensor to receive an external light. However, the quantum efficiency and the angular response of the image sensor would be poor when the external light is oblique with respect to an upper surface of the metasurface layer or a lens layer, thereby reducing the performance of the image sensor. Therefore, there is a need to solve the above problems.

### SUMMARY

The present discloses an image sensor having an enhancement layer, a chromatic dispersion layer, and a router layer. The enhancement layer and the router layer could enhance quantum efficiency (QE) and angular response of the image sensor. A first transverse layer in the enhancement layer and a second transverse layer in the router layer provide additional transverse momentum for a light, so that the light would be more easily guided to the corresponding photodiodes, thereby increasing the performance of the image sensor. The disclosed image sensor allows a larger incident angle of the light propagating in the image sensor, so as to increase the performance of the image sensor.

One aspect of the present disclosure is to provide an image sensor. The image sensor includes a photoelectric conversion layer, a color filter layer, an enhancement layer, a chromatic dispersion layer, and a router layer. The photoelectric conversion layer includes a plurality of photodiodes and a plurality of deep trench isolations separating the photodiodes. The color filter layer is disposed on the photoelectric conversion layer. The enhancement layer is disposed on the color filter layer, wherein the enhancement layer includes a plurality of first pillars, a filling, and a first transverse layer. The plurality of first pillars is disposed on the color filter layer. The filling surrounds the plurality of first pillars, and the filling is disposed on the color filter layer. The first transverse layer is disposed on the plurality of first pillars and the filling. The chromatic dispersion layer is disposed on the enhancement layer. The router layer is disposed on the chromatic dispersion layer, wherein the router layer includes a second transverse layer and a plurality of second pillars. The second transverse layer is disposed on the chromatic dispersion layer. The plurality of second pillars is disposed on the second transverse layer, wherein a critical dimension of the second pillars is smaller than a critical dimension of the first pillars, the critical dimension of the second pillars is defined by a width of a smallest one of the second pillars, and the critical dimension of the first pillars is defined by a width of a smallest one of the first pillars.

According to some embodiments of the present disclosure, a number of the second pillars is greater than a number of the first pillars, and the plurality of first pillars contact the color filter layer.

According to some embodiments of the present disclosure, a refractive index of the first pillars is greater than a refractive index of the chromatic dispersion layer, a refractive index of the second pillars is greater than the refractive index of the chromatic dispersion layer, the refractive index of the first transverse layer is different from the refractive index of the chromatic dispersion layer, and the refractive index of the second transverse layer is different from the refractive index of the chromatic dispersion layer.

According to some embodiments of the present disclosure, the color filter layer includes a first color filter, wherein a thickness of the first transverse layer, a thickness of the second transverse layer, and a thickness of the chromatic dispersion layer are based on the following equations:

$$0 < {h}_{TE} \leq \frac{1}{2} λ ; \\ 0 < {h}_{TR} \leq \frac{1}{2} λ ; \\ and \\ \sqrt{a number of cell of the first color filter} \times a pixel size \times 0.8 \geq {h}_{c} \geq \frac{1}{8} λ ,$$

wherein h_{TE} is the thickness of the first transverse layer, h_{TR} is the thickness of the second transverse layer, h_{c} is the thickness of the chromatic dispersion layer, the pixel size is defined by a distance between midlines of two of the deep trench isolations, λ is in a range of a visible light, and the first color filter includes 1 cell of color corresponding to one photodiode, 4 cells of color corresponding to 4 photodiodes, 9 cells of color corresponding to 9 photodiodes, or 16 cells of color corresponding to 16 photodiodes.

According to some embodiments of the present disclosure, the color filter layer includes a first color filter and a second color filter adjacent to the first color filter, a size or a position of one of the first pillars on the first color filter is the same as or different from a size or a position of another of the first pillars on the second color filter.

According to some embodiments of the present disclosure, a refractive index of the first pillars is the same as a refractive index of the first transverse layer, a refractive index of the second pillars is the same as a refractive index of the second transverse layer, and the refractive index of the first pillars is different from the refractive index of the second pillars.

According to some embodiments of the present disclosure, a refractive index of the first pillars is different from a refractive index of the first transverse layer, a refractive index of the second pillars is different from a refractive index of the second transverse layer, the refractive index of the first transverse layer is different from the refractive index of the second transverse layer, and the refractive index of the first pillars is the same as the refractive index of the second pillars.

According to some embodiments of the present disclosure, the first transverse layer includes a plurality of discontinuous portions, the discontinuous portions are spaced apart by the chromatic dispersion layer, each of the discontinuous portions connects each of the first pillars, respectively. A projection of each of the discontinuous portions on the color filter layer laterally beyond a projection of each of the first pillars on the color filter layer.

According to some embodiments of the present disclosure, the color filter layer includes a first color filter, and the first transverse layer has a curved top surface and a flat bottom surface, wherein an upmost thickness of the first transverse layer is based on the following equation:

$$0 < {h}_{TE} \leq \frac{1}{2} \times \sqrt{a number of cell of the first color filter} \times a pixel size ,$$

wherein h_{TE} is the upmost thickness of the first transverse layer, the pixel size is defined by a distance between midlines of two of the deep trench isolations, λ is in a range of a visible light, and the first color filter includes 1 cell of color corresponding to one photodiode, 4 cells of color corresponding to 4 photodiodes, 9 cells of color corresponding to 9 photodiodes, or 16 cells of color corresponding to 16 photodiodes.

According to some embodiments of the present disclosure, the color filter layer includes a first color filter, and the first transverse layer includes a lining layer and a plurality of trapezoids disposed on the lining layer, and a top width of each of the trapezoids is less than a bottom width of each of the trapezoids, wherein an upmost thickness of the first transverse layer is based on the following equation:

$$0 < {h}_{TE} \leq \frac{1}{2} \times \sqrt{a number of cell of the first color filter} \times a pixel size ,$$

wherein h_{TE} is the upmost thickness of the first transverse layer, the pixel size is defined by a distance between midlines of two of the deep trench isolations, λ is in a range of a visible light, and the first color filter includes 1 cell of color corresponding to one photodiode, 4 cells of color corresponding to 4 photodiodes, 9 cells of color corresponding to 9 photodiodes, or 16 cells of color corresponding to 16 photodiodes.

According to some embodiments of the present disclosure, the color filter layer includes a first color filter, and the first transverse layer includes a lining layer and a plurality of trapezoids disposed on the lining layer, and a top width of each of the trapezoids is wider than a bottom width of each of the trapezoids, wherein an upmost thickness of the first transverse layer is based on the following equation:

$$0 < {h}_{TE} \leq \frac{1}{2} \times \sqrt{a number of cell of the first color filter} \times a pixel size ,$$

wherein h_{TE} is the upmost thickness of the first transverse layer, the pixel size is defined by a distance between midlines of two of the deep trench isolations, λ is in a range of a visible light, and the first color filter includes 1 cell of color corresponding to one photodiode, 4 cells of color corresponding to 4 photodiodes, 9 cells of color corresponding to 9 photodiodes, or 16 cells of color corresponding to 16 photodiodes.

According to some embodiments of the present disclosure, a profile of each of the first pillars includes a circle, a square, a hexagon, or a petal shape, each of the first pillars has a first cavity, and a shape of the first cavity includes a circle, a square, or a hexagon. The first cavity is filled with at least a first material different from a material of the first pillars, and an equivalent refractive index of the first pillars is greater than a refractive index of the filling. A profile of each of the second pillars includes a circle, a square, a hexagon, or a petal shape, each of the second pillars has a second cavity, and a shape of the second cavity includes a circle, a square, or a hexagon. The second cavity is filled with at least a second material different from a material of the second pillars, and an equivalent refractive index of the second pillars is greater than a refractive index of a surrounding material.

According to some embodiments of the present disclosure, the color filter layer includes a first color filter and a second color filter adjacent to the first color filter, the first color filter covers two of the photodiodes, and the second color filter covers another two of the photodiodes.

According to some embodiments of the present disclosure, the first pillars have a first global shift relative to the color filter layer, and the second pillars have a second global shift relative to the color filter layer.

According to some embodiments of the present disclosure, the color filter layer includes a first color filter, one of the first pillars above the first color filter has a first inner shift relative to a first alignment line of the first color filter, and one of the second pillars above the first color filter has a second inner shift relative to a second alignment line of the first color filter.

According to some embodiments of the present disclosure, the image sensor further includes a coating layer disposed between the color filter layer and the enhancement layer, wherein the coating layer is conformal or planarized.

According to some embodiments of the present disclosure, the enhancement layer further includes a plurality of third pillars disposed on the first transverse layer, the first pillars and the third pillars are disposed on different sides of the first transverse layer, and the third pillars are spaced apart by the chromatic dispersion layer. The router layer further includes a plurality of fourth pillars disposed on the second transverse layer, the second pillars and the fourth pillars are disposed on different sides of the second transverse layer, and the fourth pillars are spaced apart by the chromatic dispersion layer.

According to some embodiments of the present disclosure, the image sensor further includes a protection layer covering the plurality of second pillars, wherein the protection layer contacts the second transverse layer.

One aspect of the present disclosure is to provide an image sensor. The image sensor includes a photoelectric conversion layer, a color filter layer, a coating layer, an enhancement layer, a chromatic dispersion layer, and a router layer. The photoelectric conversion layer includes a plurality of photodiodes. The color filter layer is disposed on the photoelectric conversion layer. The coating layer is disposed on the color filter layer, wherein the coating layer is conformal or planarized. The enhancement layer is disposed on the coating layer, wherein the enhancement layer includes a plurality of first pillars and a first transverse layer. The plurality of first pillars is disposed on the coating layer. The first transverse layer includes a plurality of discontinuous portions, each of the discontinuous portions has a lens structure, and each of the discontinuous portions connects each of the first pillars, respectively. The chromatic dispersion layer is disposed on the coating layer and surrounds the first pillars and the first transverse layer. The router layer is disposed on the chromatic dispersion layer, wherein the router layer includes a second transverse layer and a plurality of second pillars. The second transverse layer is disposed on the chromatic dispersion layer. The plurality of second pillars is disposed on the second transverse layer, wherein a critical dimension of the second pillars is smaller than a critical dimension of the first pillars, the critical dimension of the second pillars is defined by a width of a smallest one of the second pillars, and the critical dimension of the first pillars is defined by a width of a smallest one of the first pillars.

According to some embodiments of the present disclosure, the image sensor further includes a protection layer surrounding the plurality of second pillars, wherein the protection layer contacts the second transverse layer.

It is to be understood that both the foregoing general description and the following detailed description are by examples, and are intended to provide further explanation of the invention as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of an image sensor in accordance with some embodiments of the present disclosure.

FIG. 1B is a cross-sectional view of an image sensor in accordance with some embodiments of the present disclosure.

FIG. 2A is a top view of second pillars and a color filter layer of an image sensor in accordance with some embodiments of the present disclosure.

FIG. 2B is a top view of first pillars and a color filter layer of an image sensor in accordance with some embodiments of the present disclosure.

FIG. 3A, FIG. 4A, and FIG. 5A are alternative embodiments of the image sensor in FIG. 2A.

FIG. 3B, FIG. 4B, and FIG. 5B are alternative embodiments of the image sensor in FIG. 2B.

FIG. 6A is a top view of second pillars, a color filter layer and photodiodes of an image sensor in accordance with some embodiments of the present disclosure.

FIG. 6B is a top view of first pillars, a color filter layer and photodiodes of an image sensor in accordance with some embodiments of the present disclosure.

FIG. 7 to FIG. 12 are cross-sectional views of image sensors in accordance with some embodiments of the present disclosure.

FIG. 13A to FIG. 13F are top views of a first pillar and a second pillar in accordance with some alternative embodiments of the present disclosure.

FIG. 14 to FIG. 22 are cross-sectional views of image sensors in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. It should be understood that the number of any elements/components is merely for illustration, and it does not intend to limit the present disclosure.

It will be understood that, although the terms “first,” “second,” etc. may be used herein to describe various elements, these elements should not be limited by these terms. These terms are only used to distinguish one element from another. For example, a “first element” may be termed a “second element,” and, similarly, a “second element” may be termed a “first element,” without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

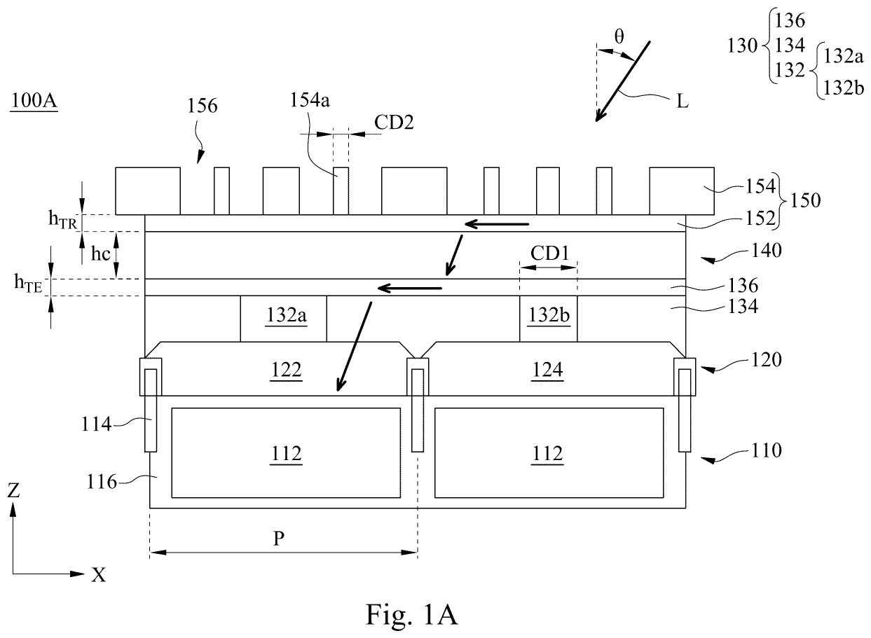

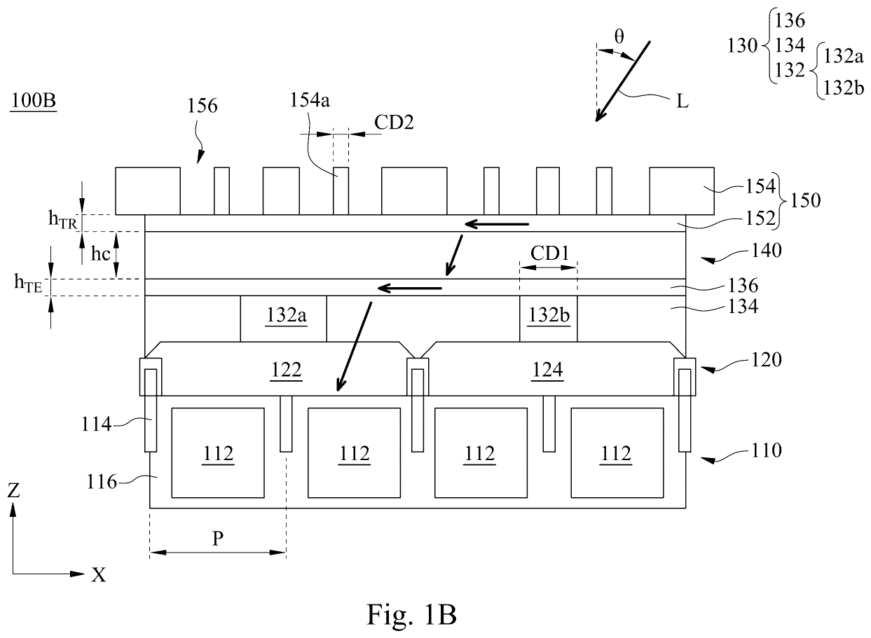

FIG. 1A is a cross-sectional view of an image sensor 100A in accordance with some embodiments of the present disclosure. The image sensor 100A includes a photoelectric conversion layer 110, a color filter layer 120, an enhancement layer 130, a chromatic dispersion layer 140, and a router layer 150. The photoelectric conversion layer includes a plurality of photodiodes (PDs) 112 and a plurality of deep trench isolations (DTIs) 114 separating the PDs 112. The color filter layer 120 is disposed on the photoelectric conversion layer 110. The enhancement layer 130 is disposed on the color filter layer 120, wherein the enhancement layer 130 includes a plurality of first pillars 132, a filling 134, and a first transverse layer 136. The plurality of first pillars 132 is disposed on the color filter layer 120. The filling 134 surrounds the plurality of first pillars 132, and the filling 134 is disposed on the color filter layer 120. The first transverse layer 136 is disposed on the plurality of first pillars 132 and the filling 134. The chromatic dispersion layer 140 is disposed on the enhancement layer 130. The router layer 150 is disposed on the chromatic dispersion layer 140, wherein the router layer 140 includes a second transverse layer 152 and a plurality of second pillars 154. The second transverse layer 152 is disposed on the chromatic dispersion layer 140. The plurality of second pillars 154 is disposed on the second transverse layer 152.

The photoelectric conversion layer 110 further includes a substrate 116. The PDs 112 and the DTIs 114 are embedded in the substrate 116. Each of the PD 112 is disposed between two DTIs 114. In some embodiments, the substrate 116 may be a single structure shared by all of the DTIs 114 and the PDs 112. The DTIs 114 are configured to avoid light interference and electrical crosstalk between adjacent PDs 112. The PDs 112 are configured to sense a light L and generate intensity signals according to the intensity of the light L propagating thereon. The intensity signals form the image signals. In some embodiments, the substrate 116 may be a semiconductor substrate, an organic photoelectric conversion substrate, a semiconductor on insulator (SOI) substrate, or another suitable substrate.

The color filter layer 120 includes a first color filter 122 and a second color filter 124 adjacent to the first color filter 122. In the embodiment of FIG. 1A, the first color filter 122 corresponds to one PD 112, and the second color filter 124 also corresponds to one PD 112.

In the embodiments of FIG. 1A, the first pillars 132 include a pillar 132a and a pillar 132b. The first pillars 132 and the filling 134 are disposed between the color filter layer 120 and the first transverse layer 136. In the embodiment of FIG. 1A, the first transverse layer 136 is a continuous layer. Specifically, the first transverse layer 136 is continuously disposed between the first pillars 132 and the filling 134 and the chromatic dispersion layer 140. Both the chromatic dispersion layer 140 and second transverse layer 152 are continuous layers. Specifically, the chromatic dispersion layer 140 is continuously disposed between the first transverse layer 136 and the second transverse layer 152, and the second transverse layer 152 is continuously disposed between the chromatic dispersion layer 140 and the second pillars 154. The chromatic dispersion layer 140 separates the first transverse layer 136 and the second transverse layer 152. The router layer 150 further includes a plurality of recesses 156 disposed between two second pillars 154. In the embodiment of FIG. 1A, the recesses 156 are filled with air, so the second pillars 154 is surrounded by the air (i.e. a surrounding material).

The second pillars 154 could be understood as a metasurface layer, so the image sensor 100A could be understood as a metasurface-based CIS. Referring to FIG. 1A, the second pillars 154 are configured to receive and disperse the light L. The light L is oblique with respect to an upper surface of the router layer 150. In other words, an incidence angle θ of the light L is not 0 degree. The light L could be understood as an inclined light. In some embodiments, the incidence angle θ of the light L is in a range from 0 degree to 60 degrees, such as 12 degrees, 15 degrees, 20 degrees, 25 degrees, 30 degrees, 35 degrees, 40 degrees, 45 degrees, 50 degrees, or 55 degrees. In the present disclosure, the light L represents a visible light.

In some embodiments, a critical dimension CD2 of the second pillars 154 is smaller than a critical dimension CD1 of the first pillars 132, wherein the critical dimension CD2 of the second pillars 154 is defined by a width of a smallest one of the second pillars 154, and the critical dimension of the first pillars 132 is defined by a width of a smallest one of the first pillars 132, as shown in FIG. 1A. In other words, a width of a pillar 154a is smaller than a width of a pillar 132b. The upper pillars (i.e., the second pillars 154) can route the incoming light L to its corresponding color filters (such as the first color filter 122 and the second color filter 124) according to the wavelengths of the light L. The smaller sizes of the second pillars 154 and the larger number of second pillars 154 are required to make the phases of light L as continuous as possible, so that the light L of different wavelengths has different phase changes with higher energy efficiency, thereby guiding the light L to the corresponding pixels. The lower pillars (i.e., the first pillars 132) can guide the light L from different incidence angles to the underlying pixels as much as possible, so the larger sizes of the first pillars 132 can attract the light L from a larger area. In other words, when the critical dimension CD2 of the second pillars 154 is smaller than the critical dimension CD1 of the first pillars 132, the quantum efficiency (QE) and the angular response of the image sensor 100A can be enhanced. If the critical dimension CD2 of the second pillars 154 was the same as or greater than the critical dimension CD1 of the first pillars 132, the function of routing the incoming light L may be reduced and the quantum efficiency (QE) and the angular response of the image sensor may be reduced.

In some embodiments, a number of the second pillars 154 is greater than a number of the first pillars 132. When the number of the second pillars 154 is greater than the number of the first pillars 132, the function of routing the incoming light L can be enhanced to make the phases of light L as continuous as possible, so that the light L of different wavelengths has different phase changes, thereby guiding the light L to the corresponding pixels. Therefore, the quantum efficiency (QE) and the angular response of the image sensor 100A can be enhanced. In some embodiments, the plurality of first pillars 132 contact the color filter layer 120, as shown in FIG. 1A.

In some embodiments, a material of the first pillar 132 is the same as or different from a material of the first transverse layer 136. In some embodiments, a material of the second pillars 154 is the same as or different from a material of the second transverse layer 152. In some embodiments, the refractive index of the first pillars 132 is the same as or different from the refractive index of the second pillars 154. In some embodiments, the refractive index of the first transverse layer 136 is the same as or different from the refractive index of the second transverse layer 152.

In some embodiments, the refractive index of the first pillars 132 is greater than a refractive index of the chromatic dispersion layer 140. In some embodiments, the refractive index of the second pillars 154 is greater than the refractive index of the chromatic dispersion layer 140. In some embodiments, the refractive index of the first transverse layer 136 is different from the refractive index of the chromatic dispersion layer 140. In some embodiments, the refractive index of the second transverse layer 152 is different from the refractive index of the chromatic dispersion layer 140. Since the refractive index of the first transverse layer 136 and the refractive index of the second transverse layer 152 are different from the refractive index of the chromatic dispersion layer 140, and the refractive index of the first pillars 132 and the refractive index of the second pillars 154 are greater than the refractive index of the chromatic dispersion layer 140, the light L could be deflected in the image sensor 100A and guided to centers of PDs 112. In some embodiments, a refractive index of the filling 134 and the refractive index of the chromatic dispersion layer 140 are less than the refractive indices of the first pillars 132, the first transverse layer 136, the second pillars 154, and the second transverse layer 152.

In some embodiments, the refractive index of the first pillars 132 is in a range from 1.4 to 2.6, such as 1.6, 1.8, 2, 2.2, or 2.4. In some embodiments, the refractive index of the second pillars 154 is in a range from 1.4 to 2.6, such as 1.6, 1.8, 2, 2.2, or 2.4. In some embodiments, the refractive index of the chromatic dispersion layer 140 is in a range from 1.1 to 1.5, such as 1.2, 1.3, or 1.4. In some embodiments, the refractive index of the first transverse layer 136 is in a range from 1.1 to 1.6, such as 1.2, 1.3, 1.4, or 1.5. In some embodiments, the refractive index of the second transverse layer 152 is in a range from 1.1 to 1.6, such as 1.2, 1.3, 1.4, or 1.5.

The arrows illustrated in FIG. 1A represent an optical path of the light L. Specifically, after the light L transmitting to the second transverse layer 152 through the second pillars 154, the second transverse layer 152 provide transverse momentum for the light L so that the light L in second transverse layer 152 propagates along a X axis direction. Next, the light L passes through the chromatic dispersion layer 140 to the first transverse layer 136, in which the first transverse layer 136 provide transverse momentum for the light L so that the light L in the first transverse layer 136 propagates along the X axis direction. Finally, the light L passes through the first pillars 132, the filling 134, and the color filter layer 120 to the PD 112 in the photoelectric conversion layer 110 so that the PD 112 could sense and generate intensity signals of light L. Because the second transverse layer 152 and the first transverse layer 136 provide transverse momentum for the light L, the light L would be more easily guided to the corresponding PD 112, thereby increasing the performance (such as QE) of the image sensor 100A. In other words, compared with an image sensor without a transverse layer(s), the disclosed image sensor with the first transverse layer 136 and the second transverse layer 152 could guide a larger portion of the light L to the corresponding PDs 112. It is understood that the light L with specific colors corresponds to its specific PDs 112, respectively.

Still referring to FIG. 1A, a thickness h_{TE} of the first transverse layer 136, a thickness h_{TR} of the second transverse layer 152, and a thickness h_{c} of the chromatic dispersion layer 140 are based on the following equations:

$$0 < {h}_{TE} \leq \frac{1}{2} λ ; \\ 0 < {h}_{TR} \leq \frac{1}{2} λ ; \\ and \\ \sqrt{a number of cell of the first color filter} \times a pixel size \times 0.8 \geq {h}_{c} \geq \frac{1}{8} λ ,$$

wherein h_{TE} is the thickness of the first transverse layer 136, h_{TR} is the thickness of the second transverse layer 152, h_{c} is the thickness of the chromatic dispersion layer 140, the pixel size P is defined by a distance between midlines of two of the deep trench isolations 114, λ is in a range of a visible light, and the first color filter 122 includes 1 cell of color corresponding to one PD 112 below the first color filter 122 (as shown in FIG. 1A), 4 cells of color corresponding to 4 PDs 112 below the first color filter 122 (as shown in FIG. 1B), 9 cells of color corresponding to 9 PDs 112 below the first color filter 122, or 16 cells of color corresponding to 16 PDs 112 below the first color filter 122.

If h_{TE} and or the h_{TR} are equal to 0, the first transverse layer 136 and the second transverse layer 152 cannot provide transverse momentum for the light L so that a larger portion of the light L would not be guided to the corresponding PDs 112 and the QE of the image sensor may be reduced. In other words, when

$${h}_{TE} \leq \frac{1}{2} λ and {h}_{TR} \leq \frac{1}{2} λ ,$$

the second transverse layer 152 and the first transverse layer 136 provide transverse momentum for the inclined light L, a larger portion of the light L tends to be guided to the corresponding PDs 112, thereby increasing the performance (such as QE) of the image sensor 100A. When he is in the above range, the light L deflects in the image sensor 100A with the second transverse layer 152 and the first transverse layer 136, so a larger portion of the light L tends to be guided to the corresponding PDs 112, thereby increasing the performance of the image sensor 100A.

Same features are labeled by the same numerical references, and descriptions of the same features are not repeated in the following figures. It should be understood that some elements (for example, the light L) are not illustrated in the following figures for clarity.

FIG. 1B is a cross-sectional view of an image sensor 100B in accordance with some embodiments of the present disclosure. The first color filter 122 corresponds to 4 PDs 112 disposed below the first color filter 122. Similarly, the second color filter 124 corresponds to 4 PDs 112 disposed below the second color filter 124. It is understood that the PDs 112 below the first color filter 122 is arranged as a 2×2 array, and the PDs 112 below the second color filter 124 is also arranged as a 2×2 array. It is noticed that the pixel size P is also defined by a distance between midlines of two of the deep trench isolations 114.

It is understood that, when the first color filter 122 includes 9 cells of color corresponding to 9 PDs 112 below the first color filter 122, the PDs 112 is arranged as a 3×3 array. When the first color filter 122 includes 16 cells of color corresponding to 16 PDs 112 below the first color filter 122, the PDs 112 is arranged as a 4×4 array.

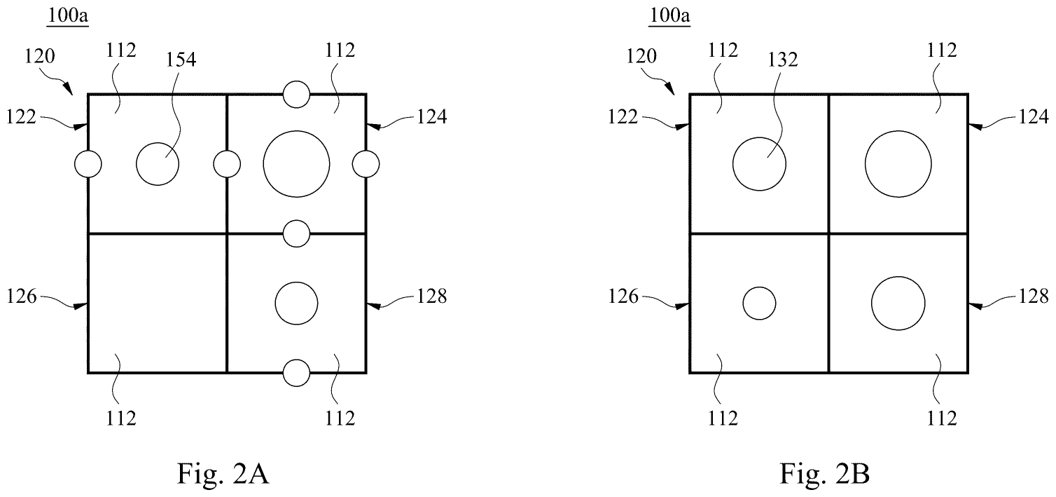

FIG. 2A is a top view of second pillars 154 and a color filter layer 120 of an image sensor 100a in accordance with some embodiments of the present disclosure. FIG. 2B is a top view of first pillars 132 and the color filter layer 120 of the image sensor 100a in accordance with some embodiments of the present disclosure. In the image sensor 100a of FIG. 2A and FIG. 2B, the color filter layer 120 includes the first color filter 122, the second color filter 124, a third color filter 126, and a fourth color filter 128. It could be understood that the number of the cell of each color filter in the image sensor 100a is 1. As shown in FIG. 2A, no second pillar 154 is disposed above the third color filter 126.

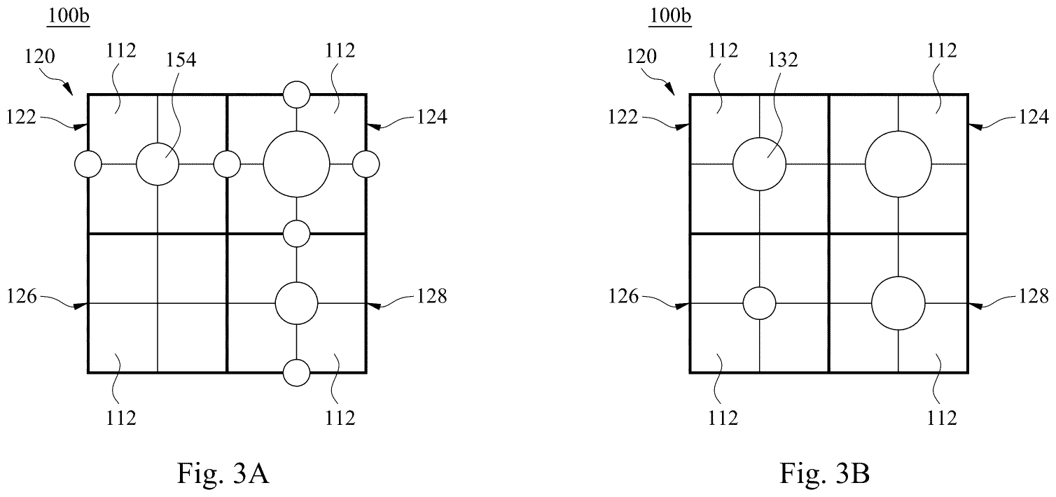

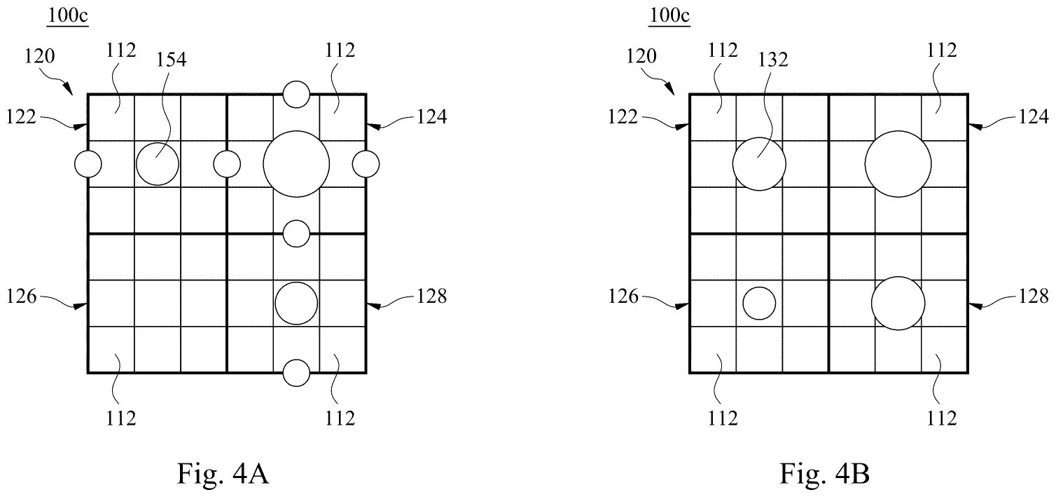

FIG. 3A, FIG. 4A, and FIG. 5A are alternative embodiments of the image sensor 100a in FIG. 2A. FIG. 3B, FIG. 4B, and FIG. 5B are alternative embodiments of the image sensor 100a in FIG. 2B.

In an image sensor 100b of FIG. 3A and FIG. 3B, the number of the cell of each color filter is 4. In an image sensor 100c of FIG. 4A and FIG. 4B, the number of the cell of each color filter is 9. In an image sensor 100d of FIG. 5A and FIG. 5B, the number of the cell of each color filter is 16.

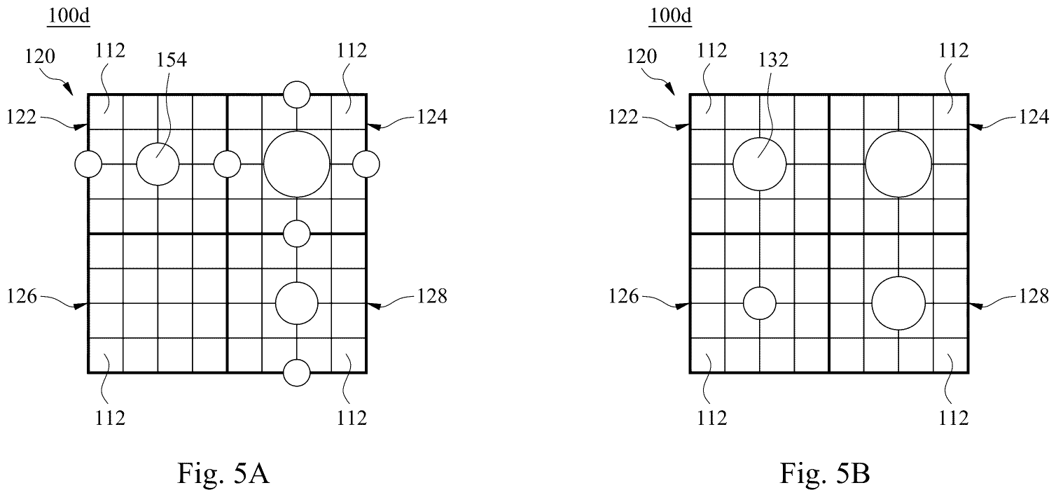

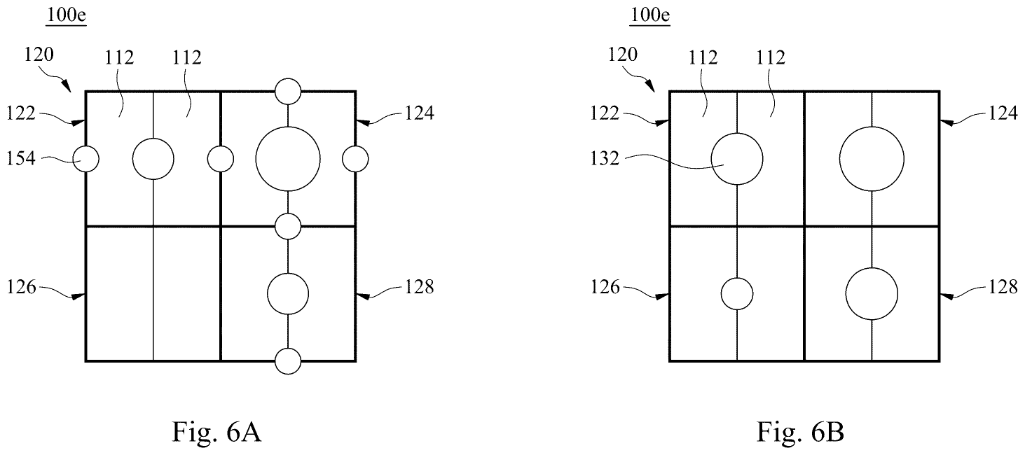

FIG. 6A is a top view of second pillars 154, a color filter layer 120, and photodiodes 112 of an image sensor 100e in accordance with some embodiments of the present disclosure. FIG. 6B is a top view of first pillars 132, a color filter layer 120, and photodiodes 112 of the image sensor 100e in accordance with some embodiments of the present disclosure. In the image sensor 100e of FIG. 6A and FIG. 6B, the first color filter 122 corresponds to dual PD (DPD), the second color filter 124 corresponds to dual PD, the third color filter 126 corresponds to dual PD, and the fourth color filter 128 corresponds to dual PD. In other words, the first color filter 122 covers two photodiodes 122, and the second color filter 124 covers another two photodiodes 122. In the embodiment of FIG. 6A, the thickness h_{c} of the chromatic dispersion layer 140 is based on the following equation:

$$2 \times a pixel size \times 0.8 \geq {h}_{c} \geq \frac{1}{8} λ .$$

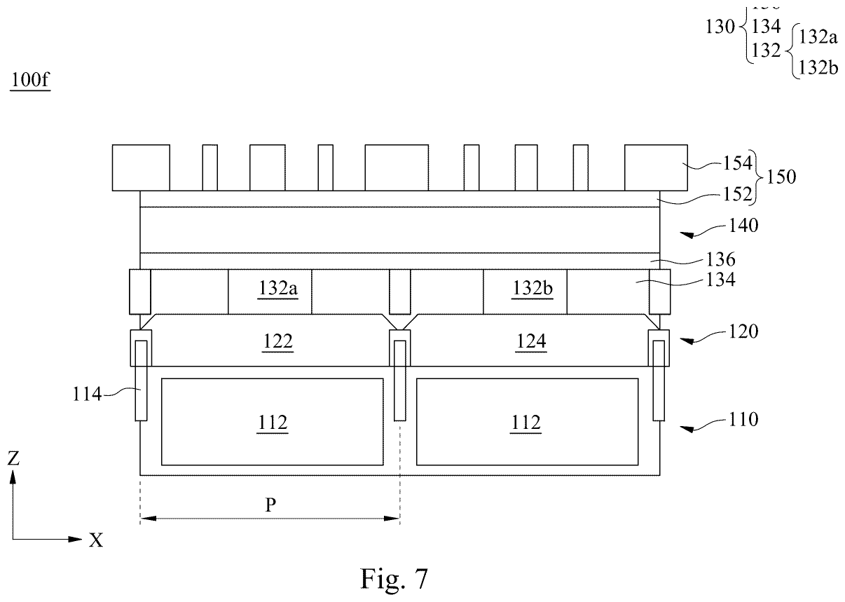

FIG. 7 is a cross-sectional view of an image sensor 100f in accordance with some embodiments of the present disclosure. The differences between the image sensor 100A in FIG. 1A and the image sensor 100f in FIG. 7 are the numbers of the first pillars 132 and the sizes of the pillars 132b. Specifically, in the image sensor 100f, a size or a position of the pillar 132a on the first color filter 122 is the same as a size or a position of the pillar 132b on the second color filter 124. More specifically, in the image sensor 100f, the size of the pillar 132a is the same as the size of the pillar 132b, and the position of the pillar 132a is the same as the position of the pillar 132b. For example, the pillar 132a stands on a center of the first color filter 122, and the pillar 132b also stands on a center of the second color filter 124.

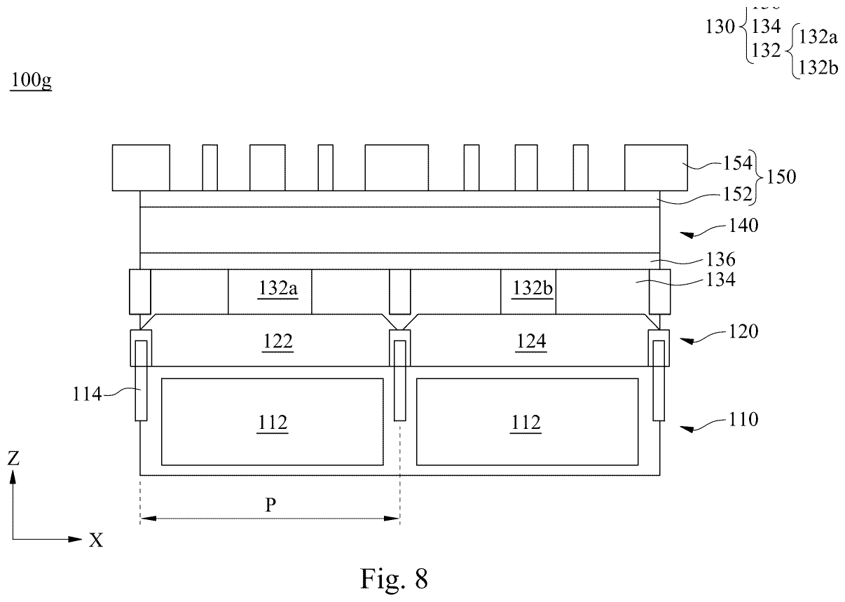

FIG. 8 is a cross-sectional view of an image sensor 100g in accordance with some embodiments of the present disclosure. The differences between the image sensor 100f in FIG. 7 and the image sensor 100g in FIG. 8 are the sizes of the pillars 132b. Specifically, in the image sensor 100g, the size or the position of the pillar 132a on the first color filter 122 is different form the size or the position of the pillar 132b on the second color filter 124. More specifically, in the image sensor 100g, the size of the pillar 132a is different form the size of the pillar 132b, but the position of the pillar 132a is the same as the position of the pillar 132b. For example, the pillar 132a stands on the center of the first color filter 122, and the pillar 132b also stands on the center of the second color filter 124.

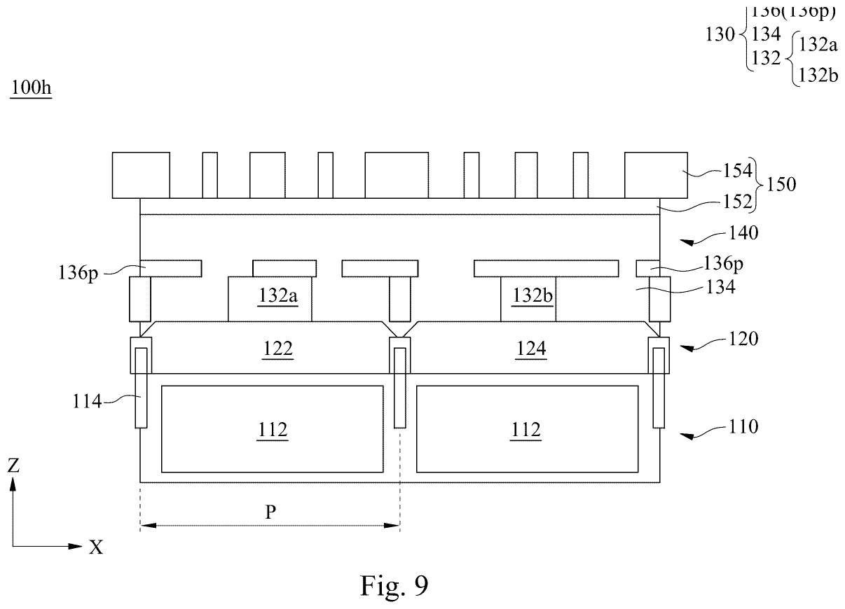

FIG. 9 is a cross-sectional view of an image sensor 100h in accordance with some embodiments of the present disclosure. The first transverse layer 136 includes a plurality of discontinuous portions 136p, the discontinuous portions are spaced apart by the chromatic dispersion layer, each of the discontinuous portions 136p connects each of the first pillars 132, respectively, as shown in FIG. 9. A projection of each of the discontinuous portions 136p on the color filter layer 120 laterally beyond a projection of each of the first pillars 132 on the color filter layer. For example, a projection of the discontinuous portion 136p on the first color filter 122 laterally beyond a projection of the pillar 132a on the first color filter 122. Similarly, a projection of the discontinuous portion 136p on the second color filter 124 laterally beyond a projection of the pillar 132b on the second color filter 124.

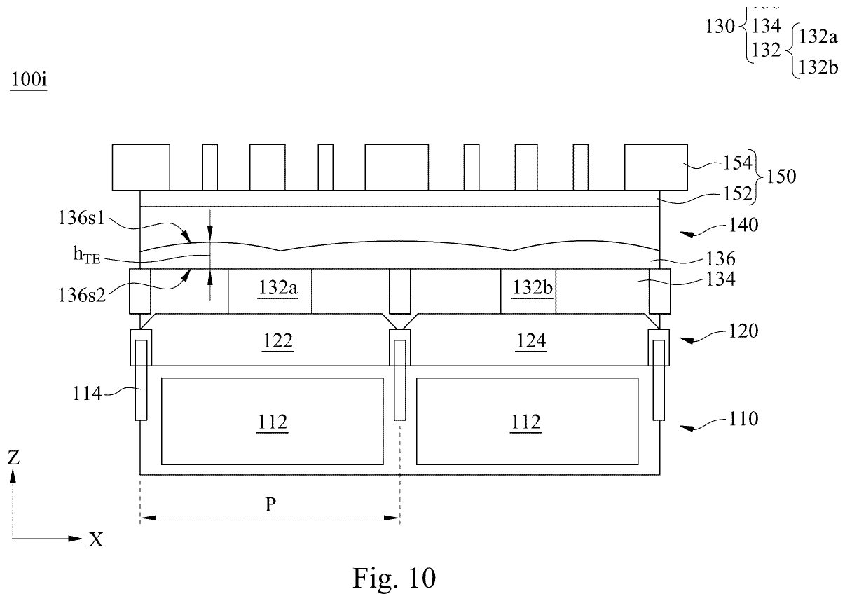

FIG. 10 is a cross-sectional view of an image sensor 100i in accordance with some embodiments of the present disclosure. The first transverse layer 136 has a curved top surface 136s1 and a flat bottom surface 136s2, wherein an upmost thickness h_{TE} of the first transverse layer 136 is based on the following equation:

$$0 < {h}_{TE} \leq \frac{1}{2} \times \sqrt{a number of cell of the first color filter} \times a pixel size ,$$

wherein h_{TE} is the upmost thickness of the first transverse layer 136, the pixel size P is defined by a distance between midlines of two of the deep trench isolations 114, λ is in a range of a visible light, and the first color filter 122 includes 1 cell of color corresponding to one PD 112 below the first color filter 122 (as shown in FIG. 10), 4 cells of color corresponding to 4 PDs 112 below the first color filter 122, 9 cells of color corresponding to 9 PDs 112 below the first color filter 122, or 16 cells of color corresponding to 16 PDs 112 below the first color filter 122. When

$${h}_{TE} \leq \frac{1}{2} \times \sqrt{a number of cell of the first color filter} \times a pixel size and {h}_{TR} \leq \frac{1}{2} λ ,$$

the second transverse layer 152 and the first transverse layer 136 provide transverse momentum for the inclined light L, a larger portion of the light L tends to be guided to the corresponding PDs 112, thereby increasing the performance (such as QE) of the image sensor 100i.

FIG. 11 is a cross-sectional view of an image sensor 100j in accordance with some embodiments of the present disclosure. The first transverse layer 136 includes a lining layer 136a and a plurality of trapezoids 136b disposed on the lining layer 136a, and a top width TW of each of the trapezoids 136b is less than a bottom width BW of each of the trapezoids 136b, wherein an upmost thickness h_{TE} of the first transverse layer 136 is based on the following equation:

$$0 < {h}_{TE} \leq \frac{1}{2} \times \sqrt{a number of cell of the first color filter} \times a pixel size ,$$

wherein h_{TE} is the upmost thickness of the first transverse layer 136, the pixel size P is defined by a distance between midlines of two of the deep trench isolations 114, λ is in a range of a visible light, and the first color filter 122 includes 1 cell of color corresponding to one PD 112 below the first color filter 122 (as shown in FIG. 11), 4 cells of color corresponding to 4 PDs 112 below the first color filter 122, 9 cells of color corresponding to 9 PDs 112 below the first color filter 122, or 16 cells of color corresponding to 16 PDs 112 below the first color filter 122. When

$${h}_{TE} \leq \frac{1}{2} \times \sqrt{a number of cell of the first color filter} \times a pixel size and {h}_{TR} \leq \frac{1}{2} λ ,$$

the second transverse layer 152 and the first transverse layer 136 provide transverse momentum for the inclined light L, a larger portion of the light L tends to be guided to the corresponding PDs 112, thereby increasing the performance (such as QE) of the image sensor 100j.

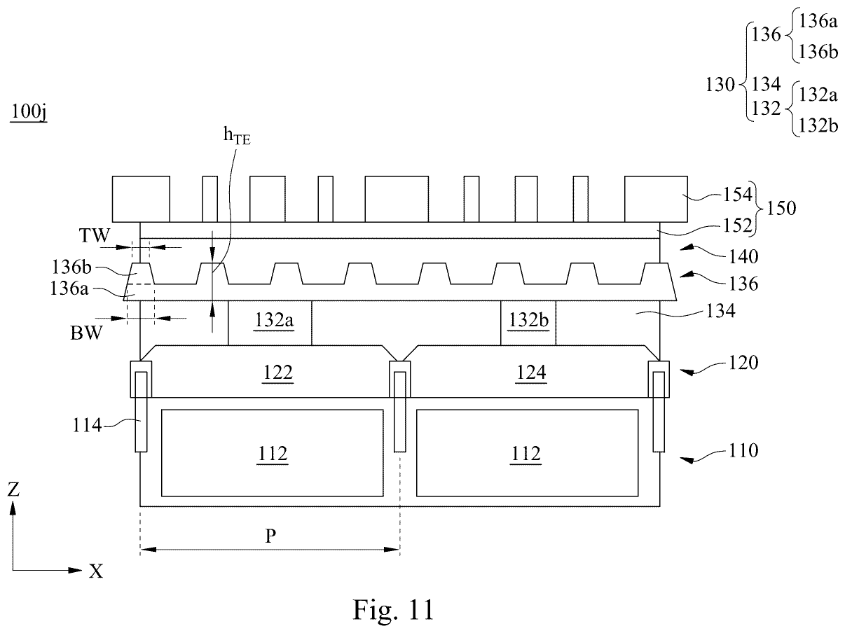

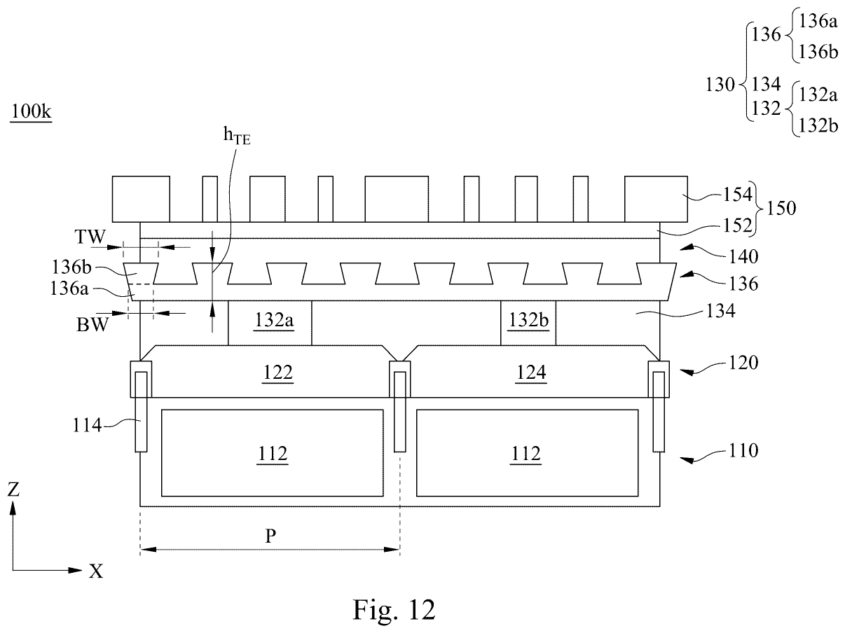

FIG. 12 is a cross-sectional view of an image sensor 100k in accordance with some embodiments of the present disclosure. The first transverse layer 136 includes a lining layer 136a and a plurality of trapezoids 136b disposed on the lining layer 136a, and a top width TW of each of the trapezoids 136b is wider than a bottom width BW of each of the trapezoids 136b, wherein an upmost thickness h_{TE} of the first transverse layer 136 is based on the following equation:

$$0 < {h}_{TE} \leq \frac{1}{2} \times \sqrt{a number of cell of the first color filter} \times a pixel size ,$$

wherein h_{TE} is the upmost thickness of the first transverse layer 136, the pixel size P is defined by a distance between midlines of two of the deep trench isolations 114, λ is in a range of a visible light, and the first color filter 122 includes 1 cell of color corresponding to one PD 112 below the first color filter 122 (as shown in FIG. 12), 4 cells of color corresponding to 4 PDs 112 below the first color filter 122, 9 cells of color corresponding to 9 PDs 112 below the first color filter 122, or 16 cells of color corresponding to 16 PDs 112 below the first color filter 122. When

$${h}_{TE} \leq \frac{1}{2} \times \sqrt{a number of cell of the first color filter} \times a pixel size and {h}_{TR} \leq \frac{1}{2} λ ,$$

the second transverse layer 152 and the first transverse layer 136 provide transverse momentum for the inclined light L, a larger portion of the light L tends to be guided to the corresponding PDs 112, thereby increasing the performance (such as QE) of the image sensor 100k.

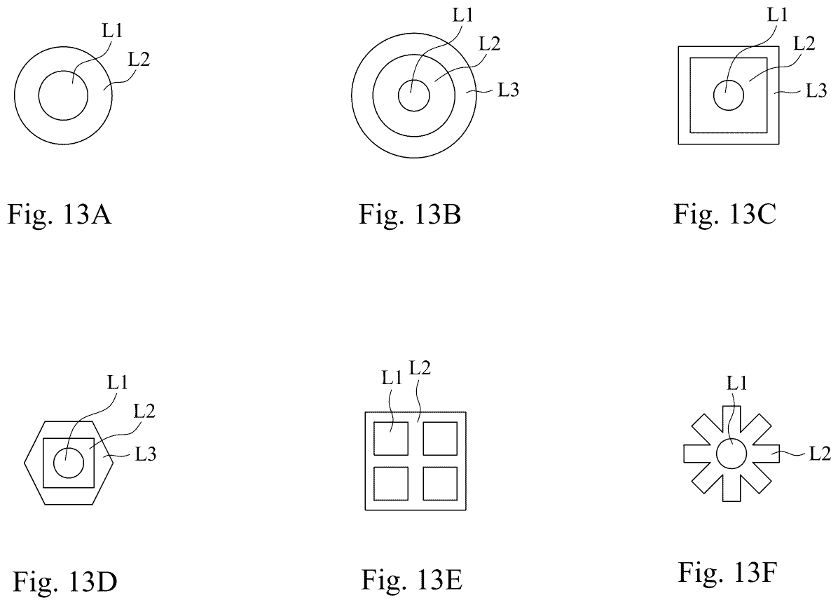

FIG. 13A to FIG. 13F are top views of the first pillar 132 and the second pillar 154 in accordance with some alternative embodiments of the present disclosure. In other words, each of the first pillars 132 and/or each of the second pillar 154 can be replaced by the structures in FIG. 13A to FIG. 13F. The first pillar 132 and the second pillar 154 in FIG. 13A to FIG. 13F has a plurality of layers.

In FIG. 13A, the first pillar 132 and/or the second pillar 154 include(s) a first layer L1 and a second layer L2 surrounding the first layer L1, and both the profiles of the first layer L1 and the second layer L2 are circles. In FIG. 13B, the first pillar 132 and/or the second pillar 154 further include(s) a third layer L3 surrounding the second layer L2, and a profile of the third layer L3 is a circle. In FIG. 13C, the profile of the first layer L1 is a circle, and both the profiles of the second layer L2 and the third layer L3 are squares. In FIG. 13D, the profile of the first layer L1 is a circle, the profile of the second layer L2 is a square, and a profile of the third layer L3 is a hexagon. In FIG. 13E, the profile of the first layer L1 includes four circles, and the profile of the second layer L2 is a square. In FIG. 13F, the profile of the first layer L1 is a circle, and the profile of the second layer L2 is a petal shape.

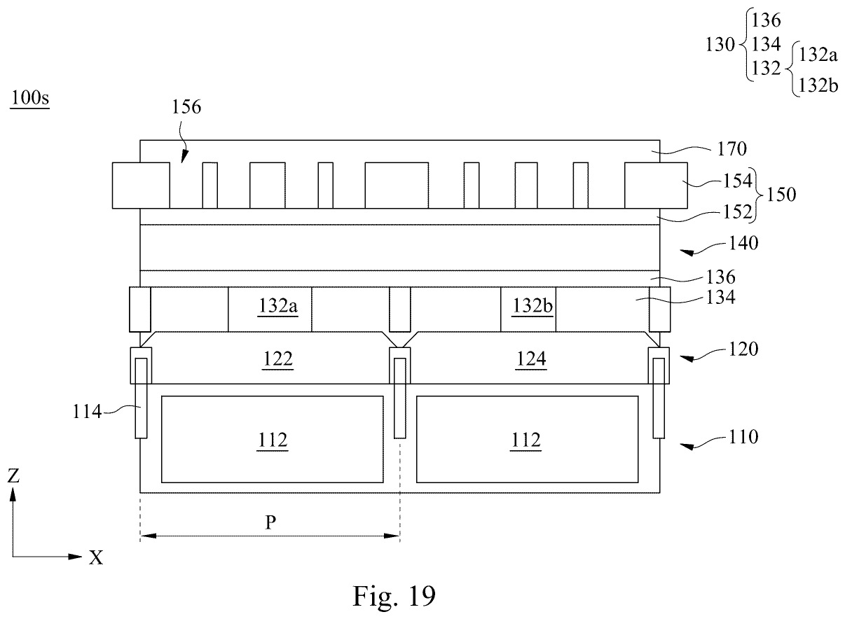

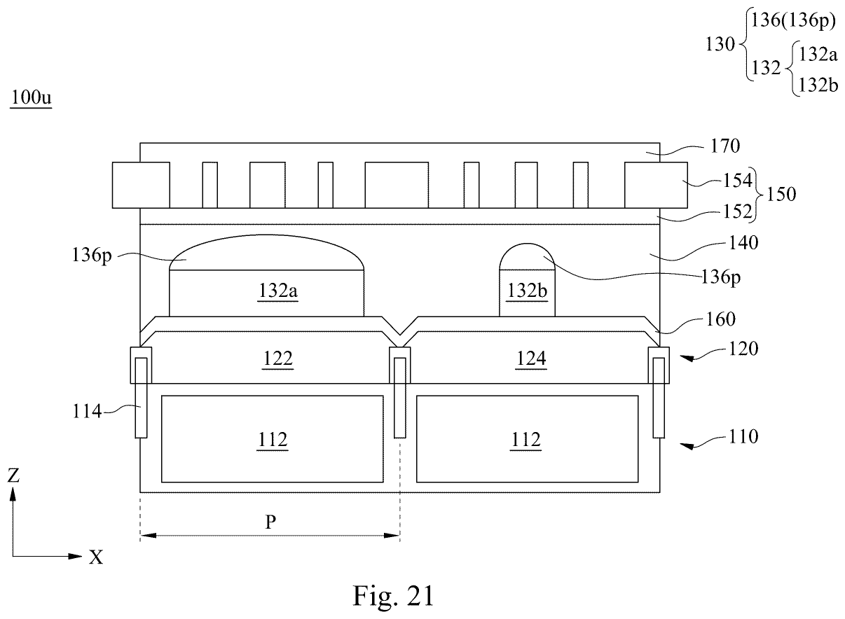

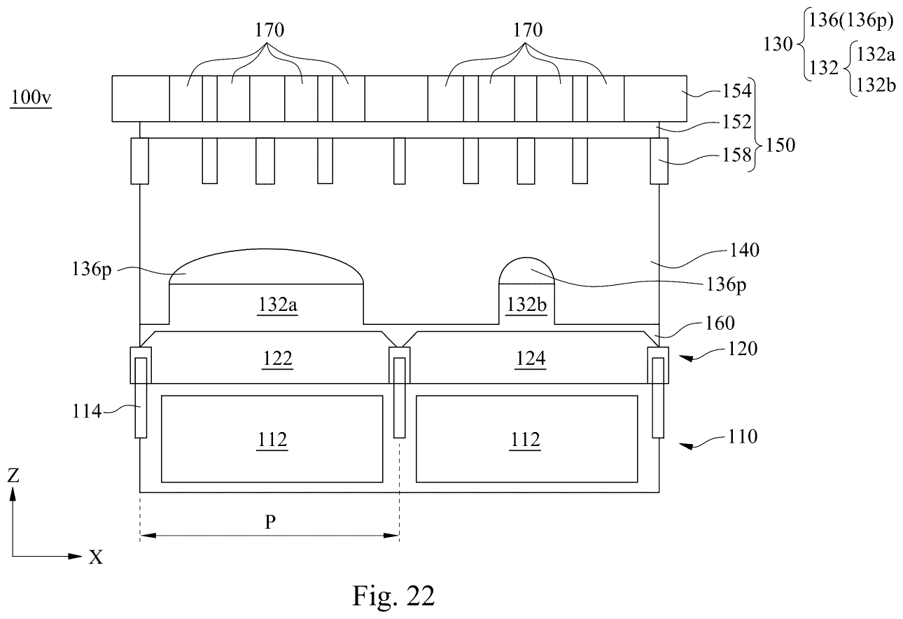

Specifically, the inner layer (such as the first layer L1 and/or the second layer L2) could be understood as a cavity so that the structures in FIG. 13A to FIG. 13F are hollow structures. In some embodiments, the cavity is filled with at least one material different from a material of the outer layer (such as the second layer L2 and/or the third layer L3). In some embodiments, an equivalent refractive index of the first pillars 132 in FIG. 13A to FIG. 13F is greater than the refractive index of the filling 134 (referring to FIG. 1A). In some embodiments, an equivalent refractive index of the second pillars 154 is greater than a refractive index of a surrounding material (such as the air in FIG. 1A or protection layers 170 in FIG. 19, FIG. 21, and FIG. 22). In one embodiment, the cavity (such as the first layer L1) of the second pillars 154 could be filled with the air.

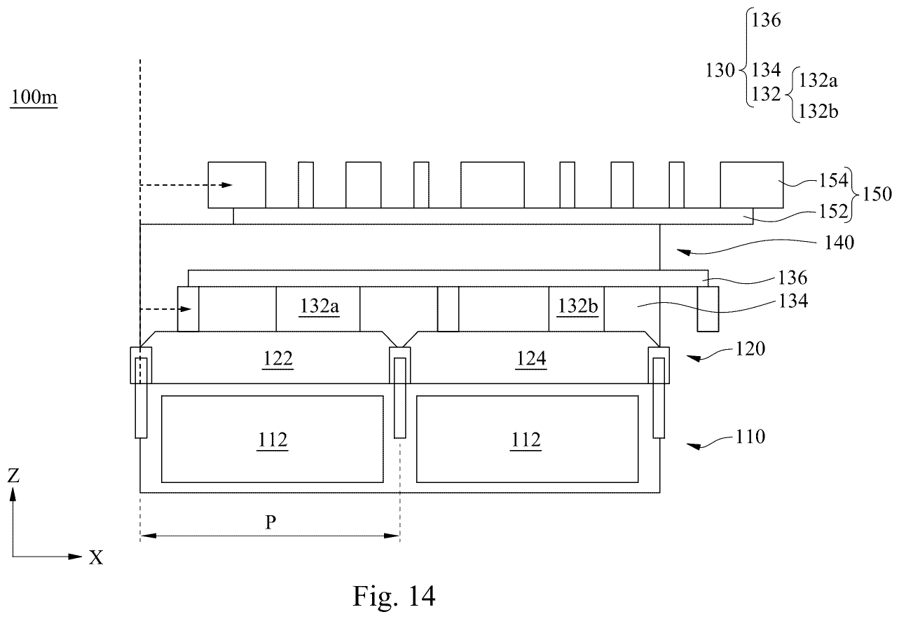

FIG. 14 is a cross-sectional view of an image sensor 100m in accordance with some embodiments of the present disclosure. The first pillars 132 have a first global shift relative to the color filter layer 120, and the second pillars 154 has a second global shift relative to the color filter layer 120. It could be understood that the term “global shift” represents one layer is shifted relative to another layer. The global shift could minimize chief ray angle (CRA) effect when the image sensor 100m is not located at the center of a chip die.

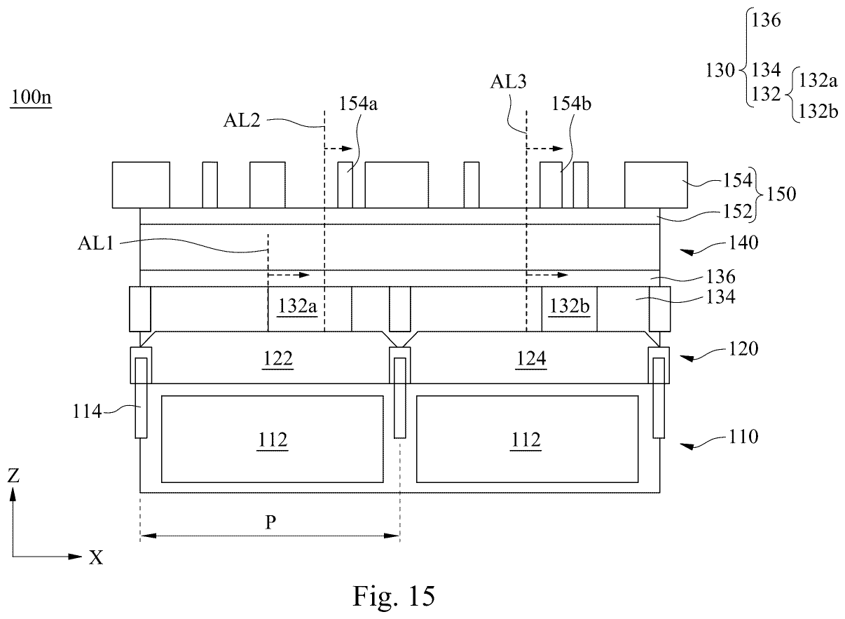

FIG. 15 is a cross-sectional view of an image sensor 100n in accordance with some embodiments of the present disclosure. One of the first pillars 132 above the first color filter 122 has a first inner shift relative to a first alignment line AL1 of the first color filter 122, and one of the second pillars 154 above the first color filter 122 has a second inner shift relative to a second alignment line AL2 of the first color filter 122. For example, as shown in FIG. 15, the pillar 132a has the inner shift relative to the first alignment line AL1 of the first color filter 122, and the pillar 154a has the inner shift relative to the second alignment line AL2 of the first color filter 122. For example, as shown in FIG. 15, the pillar 132b has the inner shift relative to a third alignment line AL3 of the second color filter 124, and a pillar 154b has the inner shift relative to the third alignment line AL3 of the second color filter 124. The inner shift could minimize chief ray angle (CRA) effect when the image sensor 100n is not located at the center of a chip die.

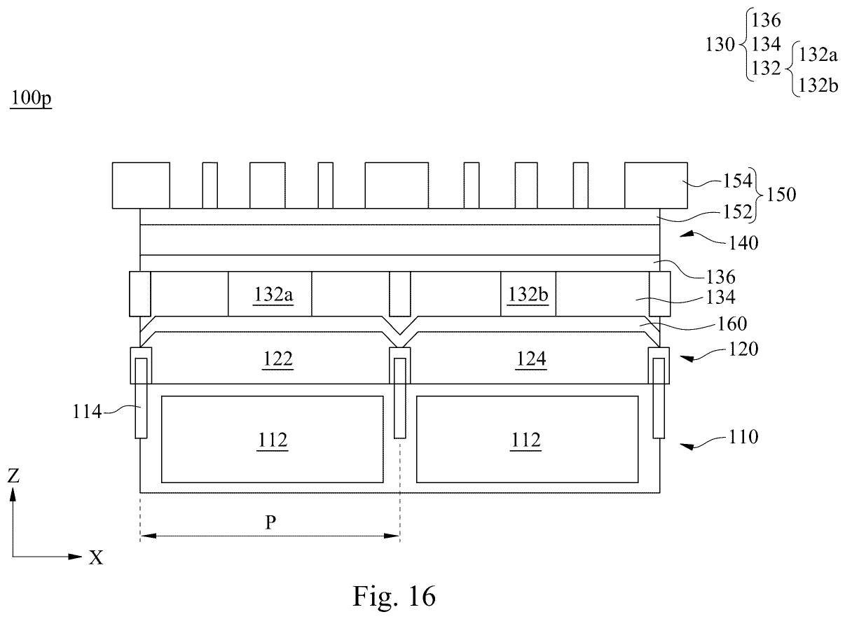

FIG. 16 is a cross-sectional view of an image sensor 100p in accordance with some embodiments of the present disclosure. The differences between the image sensor 100g in FIG. 8 and the image sensor 100p in FIG. 16 are the coating layer 160. The image sensor 100p further includes the coating layer 160 disposed between the color filter layer 120 and the enhancement layer 130, wherein the coating layer 160 is conformal. Therefore, the coating layer 160 in FIG. 16 also could be referred to as a conformal coating layer. Specifically, the coating layer 160 is disposed on a top surface of the color filter layer 120. In some embodiments, a refractive index of the coating layer 160 is in a range from 1.1 to 1.6, such as 1.2, 1.3, 1.4, or 1.5.

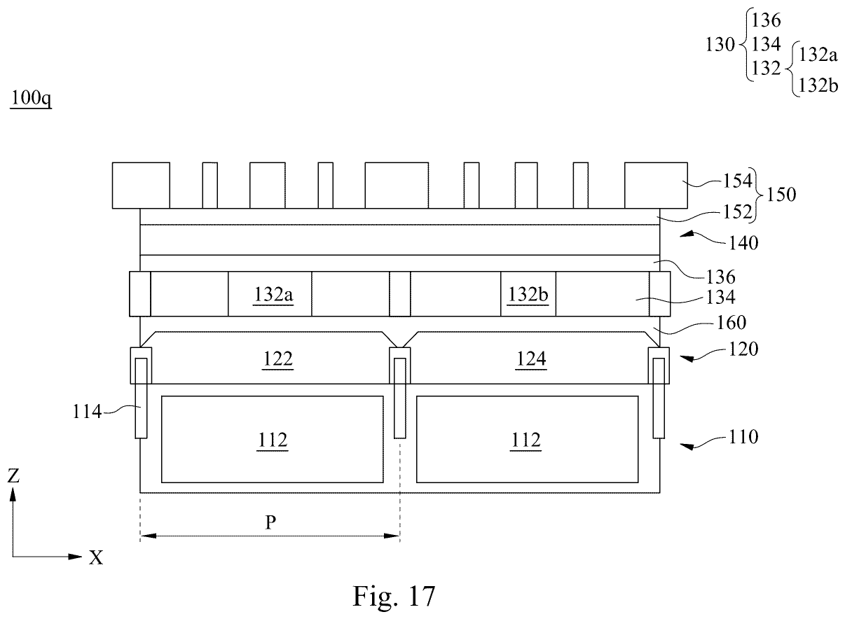

FIG. 17 is a cross-sectional view of an image sensor 100q in accordance with some embodiments of the present disclosure. The differences between the image sensor 100p in FIG. 16 and the image sensor 100q in FIG. 17 are the coating layers 160. The coating layer 160 in FIG. 17 is planarized. Therefore, the coating layer 160 in FIG. 17 also could be referred to as a planarization coating layer.

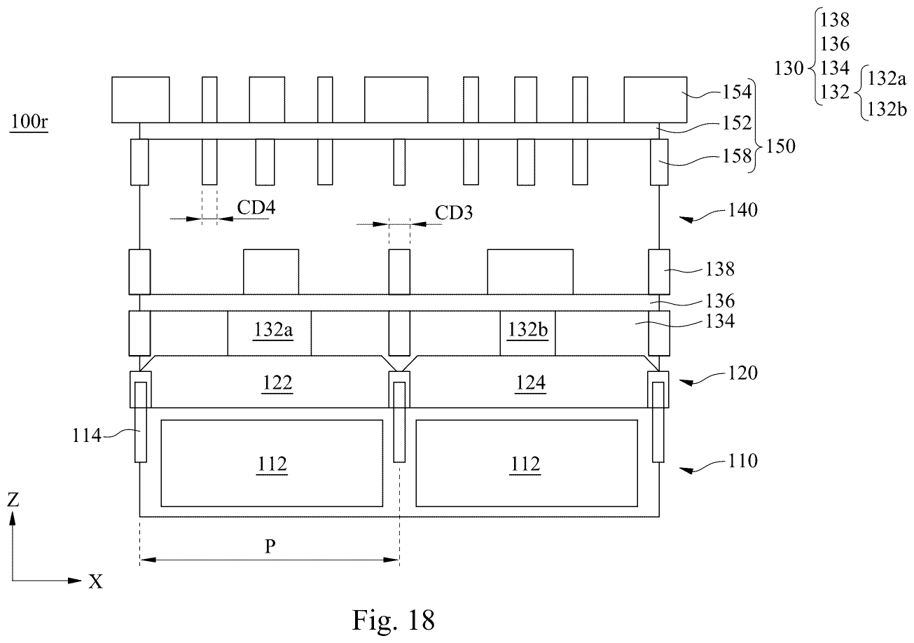

FIG. 18 is a cross-sectional view of an image sensor 100r in accordance with some embodiments of the present disclosure. The differences between the image sensor 100g in FIG. 8 and the image sensor 100r in FIG. 18 are third pillars 138 and fourth pillars 158. Specifically, as shown in FIG. 18, the enhancement layer 130 further includes a plurality of third pillars 138 disposed on the first transverse layer 136, the first pillars 132 and the third pillars 138 are disposed on different sides of the first transverse layer 136, and the third pillars 138 are spaced apart by the chromatic dispersion layer 140. The router layer 150 further includes a plurality of fourth pillars 158 disposed on the second transverse layer 152, the second pillars 154 and the fourth pillars 158 are disposed on different sides of the second transverse layer 152, and the fourth pillars 158 are spaced apart by the chromatic dispersion layer 140. In some embodiments, a critical dimension CD4 of the fourth pillars 158 is smaller than a critical dimension CD3 of the third pillars 138, wherein the critical dimension CD4 of the fourth pillars 158 is defined by a width of a smallest one of the fourth pillars 158, and the critical dimension CD3 of the third pillars 138 is defined by a width of a smallest one of the third pillars 138, as shown in FIG. 18.

FIG. 19 is a cross-sectional view of an image sensor 100s in accordance with some embodiments of the present disclosure. The differences between the image sensor 100g in FIG. 8 and the image sensor 100s in FIG. 19 is a protection layer 170. The image sensor 100s further includes the protection layer 170 covering the plurality of second pillars 154, wherein the protection layer 170 contacts the second transverse layer 152. In some embodiments, the refractive index of the second pillars 154 is greater than a refractive index of the protection layer 170. In some embodiments, the refractive index of the protection layer 170 is in a range from is in a range from 1.1 to 1.5, such as 1.2, 1.3, or 1.4.

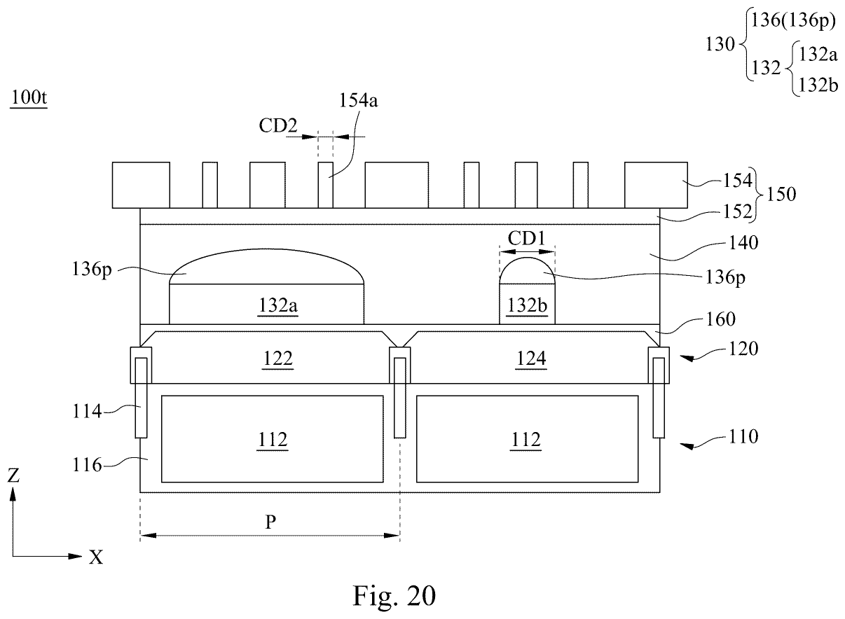

FIG. 20 is a cross-sectional view of an image sensor 100t in accordance with some embodiments of the present disclosure. The image sensor 100t includes the photoelectric conversion layer 110, the color filter layer 120, the coating layer 160, the enhancement layer 130, the chromatic dispersion layer 140, and the router layer 150. The photoelectric conversion layer 110 includes the plurality of photodiodes 112. The color filter layer 120 is disposed on the photoelectric conversion layer 110. The coating layer 160 is disposed on the color filter layer 120, wherein the coating layer 160 is conformal or planarized. The enhancement layer 130 is disposed on the coating layer 160, wherein the enhancement layer 130 includes the plurality of first pillars 132 and the first transverse layer 136. The plurality of first pillars 132 is disposed on the coating layer 160. The first transverse layer 136 includes a plurality of discontinuous portions 136p, each of the discontinuous portions 136p has a lens structure, and each of the discontinuous portions 136p connects each of the first pillars 132, respectively. The chromatic dispersion layer 140 is disposed on the coating layer 160 and surrounds the first pillars 132 and the first transverse layer 136. The router layer 150 is disposed on the chromatic dispersion layer 140, wherein the router layer 140 includes the second transverse layer 152 and the plurality of second pillars 154. The second transverse layer 152 is disposed on the chromatic dispersion layer 140. The plurality of second pillars 154 is disposed on the second transverse layer 152, wherein the critical dimension CD2 of the second pillars 154 is smaller than the critical dimension CD1 of the first pillars 132, the critical dimension CD2 of the second pillars 154 is defined by a width of a smallest one of the second pillars 154, and the critical dimension CD1 of the first pillars 132 is defined by a width of a smallest one of the first pillars 132.

In the embodiment of FIG. 20, the coating layer 160 is planarized. Therefore, the coating layer 160 in FIG. 20 also could be referred to as a planarization coating layer. In some embodiments, all the refractive indices of the first pillars 132, the second pillars 154, the first transverse layer 136, second transverse layer 152, and the coating layer 160 are the same.

FIG. 21 is a cross-sectional view of an image sensor 100u in accordance with some embodiments of the present disclosure. The differences between the image sensor 100t in FIG. 20 and the image sensor 100u in FIG. 21 are the coating layers 160 and the protection layer 170. In the embodiment of FIG. 21, the coating layer 160 is conformal. Therefore, the coating layer 160 in FIG. 21 also could be referred to as a conformal coating layer. The image sensor 100u further includes the protection layer 170 surrounding the plurality of second pillars 154, wherein the protection layer 170 contacts the second transverse layer 152. In the embodiment of FIG. 21, the protection layer 170 covers the second pillars 154. In some embodiments, all the refractive indices of the first pillars 132, the second pillars 154, the first transverse layer 136, and the second transverse layer 152 are the same.

In some embodiments, the refractive index of the first pillars 132 is different from the refractive index of the coating layer 160. In some embodiments, the refractive index of the first pillars 132 is different from the refractive index of the protection layer 170. In some embodiments, the refractive index of the protection layer 170 is different from the refractive index of the coating layer 160.

FIG. 22 is a cross-sectional view of an image sensor 100v in accordance with some embodiments of the present disclosure. The differences between the image sensor 100t in FIG. 20 and the image sensor 100v in FIG. 22 are the fourth pillars 158 and the protection layer 170. The image sensor 100v further includes the plurality of fourth pillars 158 and the protection layer 170. The second pillars 154 and the fourth pillars 158 are disposed on different sides of the second transverse layer 152, and the fourth pillars 158 are spaced apart by the chromatic dispersion layer 140. The protection layer 170 surrounding the plurality of second pillars 154, wherein the protection layer 170 contacts the second transverse layer 152.

In some embodiments, the refractive index of the first pillars 132 is different from the refractive index of the second pillars 154. In some embodiments, a material of the second pillar 154 is the same as a material of the fourth pillar 158. In some embodiments, all the refractive indices of the first pillars 132, the first transverse layer 136, and the coating layer 160 are the same. In some embodiments, all the refractive indices of the protection layer 170, the second transverse layer 152, and the chromatic dispersion layer 140 are the same.

In summary, the disclosed image sensor having the enhancement layer, the chromatic dispersion layer, and the router layer. The enhancement layer and the router layer could enhance QE and angular response of the image sensor. The first transverse layer in the enhancement layer and the second transverse layer in the router layer provide additional transverse momentum for the light, so that a larger portion of the light would be more easily guided to the corresponding photodiodes, thereby increasing the performance of the image sensor. The disclosed image sensor allows a larger incident angle of the light propagating in the image sensor, so as to increase the performance of the image sensor.

The present disclosure has been disclosed as hereinabove, however it is not used to limit the present disclosure. Those skilled in the art may make various changes, substitutions, and alterations herein without departing from the spirit and scope of the present disclosure. Therefore, the scope of protection of the present disclosure shall be subject to the scope of the claims attached in the application and its equivalent constructions.

What is claimed is:

1. An image sensor, comprising:
a photoelectric conversion layer comprising a plurality of photodiodes and a plurality of deep trench isolations separating the photodiodes;
a color filter layer disposed on the photoelectric conversion layer;
an enhancement layer disposed on the color filter layer, wherein the enhancement layer comprises:
a plurality of first pillars disposed on the color filter layer;
a filling surrounding the plurality of first pillars, wherein the filling is disposed on the color filter layer; and
a first transverse layer disposed on the plurality of first pillars and the filling;
a chromatic dispersion layer disposed on the enhancement layer; and
a router layer disposed on the chromatic dispersion layer, wherein the router layer comprises:
a second transverse layer disposed on the chromatic dispersion layer; and
a plurality of second pillars disposed on the second transverse layer, wherein a critical dimension of the second pillars is smaller than a critical dimension of the first pillars, the critical dimension of the second pillars is defined by a width of a smallest one of the second pillars, and the critical dimension of the first pillars is defined by a width of a smallest one of the first pillars.

2. The image sensor of claim 1, wherein a number of the second pillars is greater than a number of the first pillars, and the plurality of first pillars contact the color filter layer.

3. The image sensor of claim 1, wherein a refractive index of the first pillars is greater than a refractive index of the chromatic dispersion layer, a refractive index of the second pillars is greater than the refractive index of the chromatic dispersion layer, the refractive index of the first transverse layer is different from the refractive index of the chromatic dispersion layer, and the refractive index of the second transverse layer is different from the refractive index of the chromatic dispersion layer.

4. The image sensor of claim 1, wherein the color filter layer comprises a first color filter, wherein a thickness of the first transverse layer, a thickness of the second transverse layer, and a thickness of the chromatic dispersion layer are based on the following equations:
$$0 < {h}_{TE} \leq \frac{1}{2} λ ; \\ 0 < {h}_{TR} \leq \frac{1}{2} λ ; \\ and \\ \sqrt{a number of cell of the first color filter} \times a pixel size \times 0.8 \geq h\_c \geq 1 / 8 λ ,$$
wherein h_{TE} is the thickness of the first transverse layer, h_{TR} is the thickness of the second transverse layer, h_{c} is the thickness of the chromatic dispersion layer, a pixel size is defined by a distance between midlines of two of the deep trench isolations, λ is in a range of a visible light, and the first color filter comprises 1 cell of color corresponding to one photodiode, 4 cells of color corresponding to 4 photodiodes, 9 cells of color corresponding to 9 photodiodes, or 16 cells of color corresponding to 16 photodiodes.

5. The image sensor of claim 1, wherein the color filter layer comprises a first color filter and a second color filter adjacent to the first color filter, a size or a position of one of the first pillars on the first color filter is the same as or different from a size or a position of another of the first pillars on the second color filter.

6. The image sensor of claim 1, wherein a refractive index of the first pillars is the same as a refractive index of the first transverse layer, a refractive index of the second pillars is the same as a refractive index of the second transverse layer, and the refractive index of the first pillars is different from the refractive index of the second pillars.

7. The image sensor of claim 1, wherein a refractive index of the first pillars is different from a refractive index of the first transverse layer, a refractive index of the second pillars is different from a refractive index of the second transverse layer, the refractive index of the first transverse layer is different from the refractive index of the second transverse layer, and the refractive index of the first pillars is the same as the refractive index of the second pillars.

8. The image sensor of claim 1, wherein the first transverse layer comprises a plurality of discontinuous portions, the discontinuous portions are spaced apart by the chromatic dispersion layer, each of the discontinuous portions connect each of the first pillars, respectively, and
wherein a projection of each of the discontinuous portions on the color filter layer laterally beyond a projection of each of the first pillars on the color filter layer.

9. The image sensor of claim 1, wherein the color filter layer comprises a first color filter, and the first transverse layer has a curved top surface and a flat bottom surface, wherein an upmost thickness of the first transverse layer is based on the following equation:
$$0 < {h}_{TE} \leq \frac{1}{2} \times \sqrt{a number of cell of the first color filter} \times a pixel size ,$$
wherein h_{TE} is the upmost thickness of the first transverse layer, a pixel size is defined by a distance between midlines of two of the deep trench isolations, λ is in a range of a visible light, and the first color filter comprises 1 cell of color corresponding to one photodiode, 4 cells of color corresponding to 4 photodiodes, 9 cells of color corresponding to 9 photodiodes, or 16 cells of color corresponding to 16 photodiodes.

10. The image sensor of claim 1, wherein the color filter layer comprises a first color filter, and the first transverse layer comprises a lining layer and a plurality of trapezoids disposed on the lining layer, and a top width of each of the trapezoids is less than a bottom width of each of the trapezoids, wherein an upmost thickness of the first transverse layer is based on the following equation:
$$0 < {h}_{TE} \leq \frac{1}{2} \times \sqrt{a number of cell of the first color filter} \times a pixel size ,$$
wherein h_{TE} is the upmost thickness of the first transverse layer, a pixel size is defined by a distance between midlines of two of the deep trench isolations, λ is in a range of a visible light, and the first color filter comprises 1 cell of color corresponding to one photodiode, 4 cells of color corresponding to 4 photodiodes, 9 cells of color corresponding to 9 photodiodes, or 16 cells of color corresponding to 16 photodiodes.

11. The image sensor of claim 1, wherein the color filter layer comprises a first color filter, and the first transverse layer comprises a lining layer and a plurality of trapezoids disposed on the lining layer, and a top width of each of the trapezoids is wider than a bottom width of each of the trapezoids, wherein an upmost thickness of the first transverse layer is based on the following equation:
$$0 < {h}_{TE} \leq \frac{1}{2} \times \sqrt{a number of cell of the first color filter} \times a pixel size ,$$
wherein h_{TE} is the upmost thickness of the first transverse layer, a pixel size is defined by a distance between midlines of two of the deep trench isolations, λ is in a range of a visible light, and the first color filter comprises 1 cell of color corresponding to one photodiode, 4 cells of color corresponding to 4 photodiodes, 9 cells of color corresponding to 9 photodiodes, or 16 cells of color corresponding to 16 photodiodes.

12. The image sensor of claim 1, wherein a profile of each of the first pillars comprises a circle, a square, a hexagon, or a petal shape, each of the first pillars has a first cavity, and a shape of the first cavity comprises a circle, a square, or a hexagon,
wherein the first cavity is filled with at least a first material different from a material of the first pillars, and an equivalent refractive index of the first pillars is greater than a refractive index of the filling,
wherein a profile of each of the second pillars comprises a circle, a square, a hexagon, or a petal shape, each of the second pillars has a second cavity, and a shape of the second cavity comprises a circle, a square, or a hexagon, and
wherein the second cavity is filled with at least a second material different from a material of the second pillars, and an equivalent refractive index of the second pillars is greater than a refractive index of a surrounding material.

13. The image sensor of claim 1, wherein the color filter layer comprises a first color filter and a second color filter adjacent to the first color filter, the first color filter covers two of the photodiodes, and the second color filter covers another two of the photodiodes.

14. The image sensor of claim 1, wherein the first pillars have a first global shift relative to the color filter layer, and the second pillars have a second global shift relative to the color filter layer.

15. The image sensor of claim 1, wherein the color filter layer comprises a first color filter, one of the first pillars above the first color filter has a first inner shift relative to a first alignment line of the first color filter, and one of the second pillars above the first color filter has a second inner shift relative to a second alignment line of the first color filter.

16. The image sensor of claim 1, further comprising a coating layer disposed between the color filter layer and the enhancement layer, wherein the coating layer is conformal or planarized.

17. The image sensor of claim 1, wherein the enhancement layer further comprises a plurality of third pillars disposed on the first transverse layer, the first pillars and the third pillars are disposed on different sides of the first transverse layer, and the third pillars are spaced apart by the chromatic dispersion layer, and
wherein the router layer further comprises a plurality of fourth pillars disposed on the second transverse layer, the second pillars and the fourth pillars are disposed on different sides of the second transverse layer, and the fourth pillars are spaced apart by the chromatic dispersion layer.

18. The image sensor of claim 1, further comprising a protection layer covering the plurality of second pillars, wherein the protection layer contacts the second transverse layer.

19. An image sensor, comprising:
a photoelectric conversion layer comprising a plurality of photodiodes;
a color filter layer disposed on the photoelectric conversion layer;
a coating layer disposed on the color filter layer, wherein the coating layer is conformal or planarized;
an enhancement layer disposed on the coating layer, wherein the enhancement layer comprises:
a plurality of first pillars disposed on the coating layer; and
a first transverse layer comprising a plurality of discontinuous portions, each of the discontinuous portions has a lens structure, and each of the discontinuous portions connects each of the first pillars, respectively;
a chromatic dispersion layer disposed on the coating layer and surrounding the first pillars and the first transverse layer; and
a router layer disposed on the chromatic dispersion layer, wherein the router layer comprises:
a second transverse layer disposed on the chromatic dispersion layer; and
a plurality of second pillars disposed on the second transverse layer, wherein a critical dimension of the second pillars is smaller than a critical dimension of the first pillars, the critical dimension of the second pillars is defined by a width of a smallest one of the second pillars, and the critical dimension of the first pillars is defined by a width of a smallest one of the first pillars.

20. The image sensor of claim 19, further comprising a protection layer surrounding the plurality of second pillars, wherein the protection layer contacts the second transverse layer.
